(19) United States
(12) Patent Application Publication
(10) Pub. No.: US 2025/0359028 A1
(43) Pub. Date: Nov. 20, 2025

(54) SEMICONDUCTOR DEVICE AND METHOD FOR OPERATING THE SAME

(71) Applicant: TAIWAN SEMICONDUCTOR MANUFACTURING COMPANY, LTD., Hsinchu (TW)

(72) Inventor: Perng-Fei YUH, Walnut Creek, CA (US)

(73) Assignee: TAIWAN SEMICONDUCTOR MANUFACTURING COMPANY, LTD., Hsinchu (TW)

(21) Appl. No.: 18/663,868

(22) Filed: May 14, 2024

(51) Int. Cl. H10B 12/00; G11C 11/16; H01L 23/50

(52) U.S. Cl. CPC H10B 12/482; G11C 11/1655; H01L 23/50; H10B 12/488

(57) ABSTRACT

A semiconductor device is provided. The semiconductor device includes a circuit and a first bit-cell array. The circuit is coupled to a first power rail and a second power rail. The first bit-cell array comprises a first sub-array having multiple first bit-cells that are coupled between the first power rail and the second power rail. The first bit-cells are configured as a decoupling capacitor between the first and second power rails for the circuit in response to a first operational voltage on the first power rail and a second operational voltage on the second power rail.

### BACKGROUND

Circuits like a power delivery network for high-bandwidth memory and high-speed computation requires large decoupling capacitance to reduce power and ground bounce. With the increasing density and shrinking size of integrated circuits designed recently, the performance and efficiency required for the decoupling capacitors are increasing accordingly. For example, higher capacitance per area rate, fewer front-end device usage, lower leakage current and fewer back-end metal usage, etc. are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device in accordance with some embodiments of the present disclosure.

FIG. 2 is a schematic diagram of a semiconductor device corresponding to the semiconductor device shown in FIG. 1, in accordance with some embodiments of the present disclosure.

FIG. 3 is a schematic diagram of the bit-cell array in the semiconductor devices shown in FIGS. 1-2, in accordance with some embodiments of the present disclosure.

FIG. 4 is a schematic diagram of the bit-cell array in the semiconductor devices shown in FIGS. 1-2, in accordance with some embodiments of the present disclosure.

FIGS. 5 and 6 are schematic diagrams of the sub-array in the bit-cell array shown in FIGS. 4, in accordance with some embodiments of the present disclosure.

FIG. 7 is a schematic diagram of a semiconductor device corresponding to the semiconductor device shown in FIG. 1 and the semiconductor device shown in FIG. 2, in accordance with some embodiments of the present disclosure.

FIG. 8 is a schematic diagram of a cross-sectional view of the semiconductor device shown in FIG. 7, in accordance with some embodiments of the present disclosure.

FIG. 9 is a schematic diagram of a portion of the semiconductor device shown in FIGS. 7-8, in accordance with some embodiments of the present disclosure.

FIG. 10 is a schematic diagram of a semiconductor device corresponding to the semiconductor device shown in FIG. 7, in accordance with some embodiments of the present disclosure.

FIG. 11 is a schematic diagram of a cross-sectional view of the semiconductor device shown in FIG. 10, in accordance with some embodiments of the present disclosure

FIG. 12 is a schematic diagram of a portion of the semiconductor device shown in FIG. 10, in accordance with some embodiments of the present disclosure.

FIG. 13 is a schematic diagram of a semiconductor device corresponding to the semiconductor device shown in FIG. 7, in accordance with some embodiments of the present disclosure.

FIG. 14 is a schematic diagram of a semiconductor device corresponding to the semiconductor device shown in FIG. 10, in accordance with some embodiments of the present disclosure.

FIG. 15 is a schematic diagram of a semiconductor device corresponding to the semiconductor devices shown in FIGS. 7-14, in accordance with some embodiments of the present disclosure.

FIGS. 16A-16B are schematic diagrams of a semiconductor device corresponding to the semiconductor devices shown in FIGS. 1-15, in accordance with some embodiments of the present disclosure.

FIGS. 17A and 17B are example timing diagrams of voltage signals of the semiconductor device in a test operation, in accordance with some embodiments of the present disclosure.

FIG. 18 is schematic diagrams of a bit-cell corresponding to the bit-cell in the semiconductor devices shown in FIGS. 1-15, in accordance with some embodiments of the present disclosure.

FIG. 19 is a schematic diagram of a semiconductor device corresponding to the semiconductor devices shown in FIGS. 1-15, 16A-16B and 17A-17B in accordance with some embodiments of the present disclosure.

FIGS. 20A and 20B are example timing diagrams of voltage signals of the semiconductor device in a test operation, in accordance with some embodiments of the present disclosure.

FIG. 21 is a schematic diagram of a semiconductor device corresponding to the semiconductor devices shown in FIGS. 1-15, 16A-16B, 17A-17B, 18-19 and 20A-20B in accordance with some embodiments of the present disclosure.

FIGS. 22A and 22B are schematic diagrams of a portion of the semiconductor device shown in FIG. 21 in accordance with some embodiments of the present disclosure.

FIG. 23 is a schematic diagram of a semiconductor device corresponding to the semiconductor devices shown in FIGS. 1-15, 16A-16B, 17A-17B, 18-19, 20A-20B, 21 and 22A-22B in accordance with some embodiments of the present disclosure.

FIG. 24 is a flowchart diagram of a method for operating the memory devices shown in FIGS. 1-15, 16A-16B, 17A-17B, 18-19, 20A-20B, 21, 22A-22B and 23, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “above”, “upper” and the like, may be used herein for ease of description to describe one element or feature's relationship to another element(s) or feature(s) as illustrated in the FIGS. The spatially relative terms are intended to encompass different orientations of the device in use or operation in addition to the orientation depicted in the FIGS. The apparatus may be otherwise oriented (rotated 90 degrees or at other orientations) and the spatially relative descriptors used herein may likewise be interpreted accordingly.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., are used herein to describe various elements, these elements should not be limited by these terms. These terms are used to distinguish one element from another. For example, a first element could be termed a second element, and, similarly, a second element could be termed a first element, without departing from the scope of the embodiments.

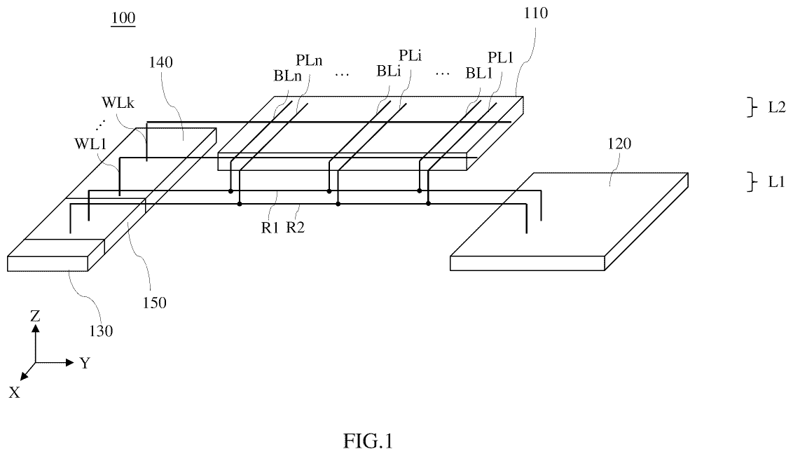

Reference is now made to FIG. 1. FIG. 1 is a schematic diagram of a semiconductor device 100 in accordance with some embodiments of the present disclosure. For illustration, the semiconductor device 100 includes bit-cell array 110, circuit 120, control circuit 130 and power rails R1 and R2. The bit-cell array 110 includes multiple bit lines BL (including bit lines BL1-BLn), multiple plate lines PL (including plate lines PL1-PLn) and multiple word lines WL (including word lines WL1-WLk). In some embodiments, the bit-cell array 110 is coupled to the power rails R1 and R2 through the bit lines BL and the plate lines PL respectively. The circuit 120 is coupled to the power rails R1 and R2. According to some embodiments of the present disclosure, the circuit 120 operates with supply (operational) voltages provided by the power rails R1 and R2. In some embodiment, the circuit 120 includes a charge pump, a digital low drop-out regulator (LDO), or any circuit that requires decoupling capacitors in operation. In some embodiments, the bit-cell array 110 provides decoupling capacitors for the circuit 120. In some embodiments, the control circuit 130 is coupled to the word lines WL and the power rails R1 and R2. The control circuit 130 controls voltages on the word lines WL and the power rails R1 and R2. In some embodiments, the control circuit 130 includes a word line driver circuit 140 controlling the voltages on the word lines WL. In some embodiments, the control circuit 130 includes a power control circuit 150 controlling the voltages on the power rails R1 and R2.

In some embodiments, the bit-cell array 110 is a memory array. In some embodiments, the bit-cell array 110 is a back-end (back-end-of-line) memory array. In some embodiments, the bit-cell array 110 is a dynamic random-access memory (DRAM) array. In some embodiments, the bit-cell array 110 is a back-end DRAM array.

As shown in FIG. 1, in some embodiments, the circuit 120 is arranged in a layer L1 and the bit-cell array 110 is arranged in a layer L2. According to various embodiments of the present closure, the layers L1 and L2 are different from each other and separated from each other in Z direction. For example, in some embodiments, the layer L1 includes metal layers different from metal layers included in the layer L2. In some embodiments, the layer L1 corresponds to back-end layers and layer L2 corresponds to front-end (front-end-of-line) layers.

In some embodiments, the control circuit 130 is arranged in the layer L1. In some embodiments, the bit-cell array 110 and the circuit 120 are in a same chip and the control circuit 130 is excluded from or partially excluded from the chip.

The configurations of FIG. 1 are given for illustrative purposes. Various implements are within the contemplated scope of the present disclosure. For example, in some embodiments, the bit cell array 110 is below the circuit 120 along the direction Z.

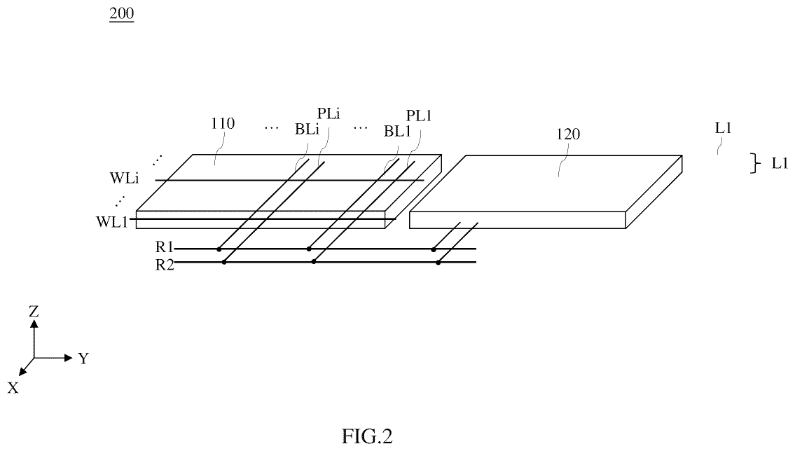

Reference is now made to FIG. 2. FIG. 2 is a schematic diagram of a semiconductor device 200 corresponding to the semiconductor device 100 shown in FIG. 1, in accordance with some embodiments of the present disclosure. With respect to the embodiments of FIG. 1, like elements in FIG. 2 are designated with the same reference numbers for ease of understanding. The specific operations of similar elements, which are already discussed in detail in above paragraphs, are omitted herein for the sake of brevity. In some embodiments, the semiconductor device 200 is configured with respect to, for example, the semiconductor device 100 of FIG. 1.

For illustration, as shown in FIG. 2, the bit-cell array 110 and the circuit 120 are arranged in a same layer in some embodiments. For example, the bit-cell array 110 and the circuit 120 are arranged in the layer L1. In some embodiments, the bit-cell array 110 and the circuit 120 are arranged in front-end layers. In some embodiments, the bit-cell array 110 and the circuit 120 are arranged in back-end layers.

The configurations of FIG. 2 are given for illustrative purposes. Various implements are within the contemplated scope of the present disclosure. For example, in some embodiments, the power rail R1 and/or the power rail R2 are above/below the layer L1 along the direction z.

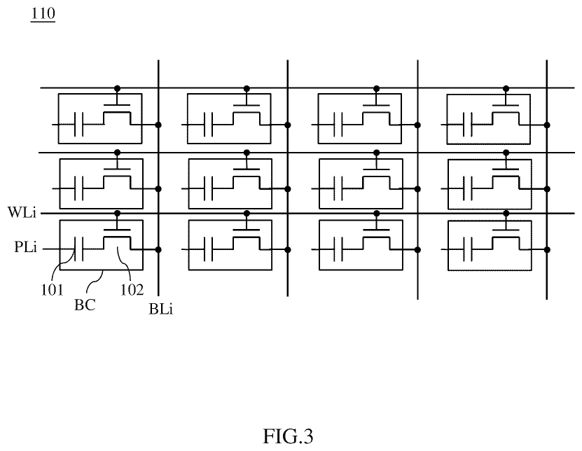

Reference is now made to FIG. 3. FIG. 3 is a schematic diagram of the bit-cell array 110 in the semiconductor devices 100-200 shown in FIGS. 1-2, in accordance with some embodiments of the present disclosure.

For illustration, the bit-cell array 110 of FIG. 3 further includes multiple bit-cells BC arranged in rows and columns. Each bit-cell BC is coupled to one of the bit lines BL (e.g., bit line BLi), one of the word lines WL (e.g., word line WLi) and one of the plate lines PL (e.g., plate line PLi). In some embodiments, bit-cells BC in a row are coupled to a same word line WL and bit-cells BC in a column are coupled to a same bit line BL.

The bit-cell array 110 operates as a decoupling capacitor by providing decoupling capacitance to the circuit 120 through the bit lines BL coupled to the power rail R1 and through the plate lines PL coupled to the power rail R2.

In some embodiments, the bit-cell BC includes a DRAM cell. In some embodiments, the bit-cell BC is a back-end DRAM cell. As shown in FIG. 3, the bit-cell BC includes a capacitor 101 and a transistor 102. The capacitor 101 is coupled between a plate line (e.g., plate line PLi) and a source/drain terminal of the transistor 102. A drain/source terminal of the transistor 102 is coupled to a bit line (e.g., bit line BLi). A control terminal (gate terminal) of the transistor 102 is coupled to a word line (e.g., word line WLi). In some embodiments, the transistor 102 is a thin-film transistor. In some embodiments, the transistor 102 is an n type transistor. In some embodiments, the transistor 102 is a p type transistor.

The configurations of FIG. 3 are given for illustrative purposes. Various implements are within the contemplated scope of the present disclosure. For example, in some embodiments, the bit-cell array 110 includes more/less bit-cells BC than the bit-cells BC shown in FIG. 3.

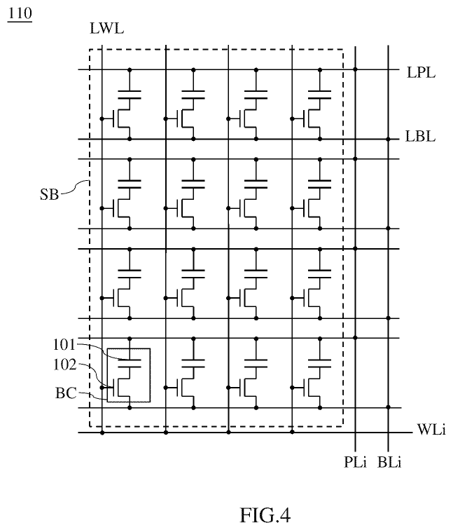

Reference is now made to FIG. 4. FIG. 4 is a schematic diagram of the bit-cell array 110 in the semiconductor devices 100-200 shown in FIGS. 1-2, in accordance with some embodiments of the present disclosure.

In some embodiments, the bit-cell array 110 of FIG. 4 is configured with respect to, for example, the bit-cell array 110 of FIG. 3. The difference between the bit-cell array 110 of FIG. 4 and the bit-cell array 110 of FIG. 3 is that the bit-cell array 110 of FIG. 3 includes one or more sub-arrays SB including multiple bit-cells BC. The bit-cells BC in the same sub-array SB are coupled to a same bit line BL (e.g., bit line BLi), a same word line WL (e.g., word line WLi) and a same plate lines PL (e.g., plate line PLi). In some embodiments, the same bit line BL of the sub-array SB is coupled to the power rail R1 and the same plate line PL of the sub-array SB is coupled to the power rail R2; and the sub-array SB provides decoupling capacitance between the power rails R1 and R2 for the circuit 120.

As shown in FIG. 4, the capacitor 101 of each bit-cell BC in the sub-array SB is coupled between the same plate line (e.g., plate line PLi) and a source/drain terminal of a corresponding transistor 102. A drain/source terminal of the transistor 102 of each bit-cell BC in the sub-array SB is coupled to the same bit line (e.g., bit line BLi). A control terminal (gate terminal) of the transistor 102 of each bit-cell BC in the sub-array SB is coupled to the same word line (e.g., word line WLi).

In some embodiments, the bit-cells BC in the sub-array SB are arranged in columns and rows. The capacitors 101 of the bit-cells BC in a same row are coupled to a same local plate line LPL. The drain/source terminals of the transistors 102 of the bit-cells BC in the same row are coupled to a same local bit line LBL. The control terminals (gate terminals) of the transistors 102 of bit-cells BC in a same column are coupled to a same local word line.

In some embodiments, the local plate lines LPL are coupled to the same plate line PL of the sub-array SB. In some embodiments, the local bit lines LBL are coupled to the same bit line BL of the sub-array SB. In some embodiments, the local word lines LWL are coupled to the same word line WL of the sub-array SB. In some embodiments, the same plate line PL of the sub-array SB extends along a first direction (e.g., direction X) and the local plate lines LPL of the sub-array SB extend along a second direction perpendicular to the first direction (e.g., direction Y). Similarly, In some embodiments, the same bit line BL of the sub-array SB extends along a first direction (e.g., direction X) and the local bit lines LBL of the sub-array SB extend along a second direction perpendicular to the first direction (e.g., direction Y). In some embodiments, the local word lines LWL of the sub-array SB extend along a first direction (e.g., direction X) and the same word lines WL of the sub-array SB extends along a second direction perpendicular to the first direction (e.g., direction Y). The configurations of FIG. 4 are given for illustrative purposes. Various implements are within the contemplated scope of the present disclosure. For example, in some embodiments, the sub-array SB includes more/less bit-cells BC than the bit-cells BC shown in FIG. 3. In some embodiments, the bit-cell array 110 includes multiple sub-arrays SB that have different numbers of bit-cells BC.

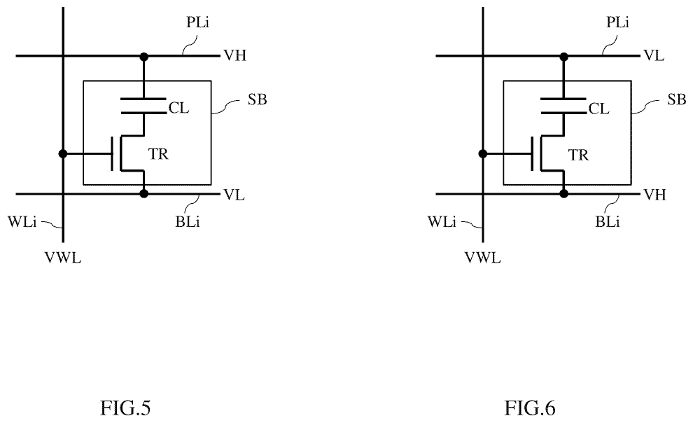

Reference is now made to FIG. 5 and FIG. 6. FIGS. 5 and 6 are schematic diagrams of the sub-array SB in the bit-cell array 110 shown in FIGS. 4, in accordance with some embodiments of the present disclosure.

FIGS. 5 and 6 show equivalent circuits of the circuit shown in FIG. 4. For the sake of simplicity, a lump capacitor CL in FIGS. 5 and 6 is an equivalent capacitor of all the capacitors 101 in the sub-array SB of FIG. 4. A transistor TR in FIGS. 5 and 6 is an equivalent transistor of all the transistors 102 in the sub-array SB.

In the embodiments of FIG. 5, the power rails R1 and R2 (not shown in FIG. 5) transmit a voltage VL and a voltage VH respectively. Accordingly, the plate line (e.g., plate line PLi) coupled to a sub-array SB is applied with the voltage VH. The bit line (e.g., bit line BLi) coupled to the sub-array SB is applied with the voltage VL. The word line (e.g., word line WLi) coupled to the sub-array SB is applied with a voltage VWL. In some embodiments, the voltage VH is higher than the voltage VL. The voltage VWL is a word line voltage used to select bit-cells BC (i.e., to turn on the transistor 102 in a bit-cell BC). In some embodiments, the voltage VH corresponds to a supply voltage VDD (e.g., 1 volt) or a supply voltage VDDIO of the semiconductor device 100 and the voltage VL corresponds to a reference voltage VSS of the semiconductor device 100. In some embodiments, the reference voltage VSS is a grounded voltage (0 volts). In another embodiment, the voltage VH is the reference voltage VSS and the voltage VL is a negative voltage VNEG. For example, according to some embodiments, the voltage VH is 0 volts, the voltage VL is around −0.5 volts and the voltage VWL is 0 or around 1 volt.

Instead of the power rails R1 and R2 transmitting the voltage VL and the voltage VH respectively in the embodiments of FIG. 5, in the embodiments of FIG. 6, the power rails R1 and R2 (not shown in FIG. 6) transmit the voltage VH and the voltage VL respectively. Accordingly, the plate line (e.g., plate line PLi) coupled to the sub-array SB is applied with the voltage VL and the bit line (e.g., bit line BLi) coupled to the sub-array SB is applied with the voltage VH in the embodiments of FIG. 6.

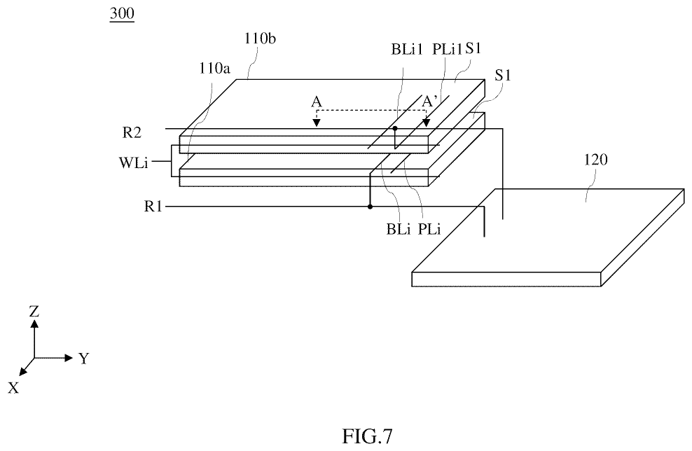

Reference is now made to FIG. 7. FIG. 7 is a schematic diagram of a semiconductor device 300 corresponding to the semiconductor device 100 shown in FIG. 1 and the semiconductor device 200 shown in FIG. 2, in accordance with some embodiments of the present disclosure. With respect to the embodiments of FIGS. 1-6, like elements in FIG. 7 are designated with the same reference numbers for ease of understanding. In some embodiments, the semiconductor device 300 is configured with respect to, for example, the semiconductor device 100 of FIG. 1 or the semiconductor device 200 of FIG. 2.

The difference between the semiconductor device 300 and the semiconductor devices 100-200 is that the semiconductor device 300 includes two bit-cell arrays 110a-110b stacked together. The bit-cell arrays 110a-110b are configured with respect to, for example, the bit-cell array 110. According to some embodiments, each of the bit-cell arrays 110a-110b has a top side S1 and a bottom side S2. In some embodiments, the top sides S1 of the two stacked bit-cell arrays 110a-110b are arranged toward a same direction (e.g., upward along the z direction). As shown in FIG. 7, the bit-cell arrays 110a is arranged below the bit-cell array 110b. Furthermore, the power rail R2 is above the bit-cell array 110b and the power rail R1 is below the bit-cell array 110a.

For illustration, the bit-cell array 110a includes a sub-array SBi (not shown in FIG. 7) configured with respect to the sub-array SB. The sub-array SBi is coupled to a bit line BLi a plate line PLi. The bit line BLi is coupled to the power rail R1 that is coupled to the circuit 120.

Similarly, the other bit-cell array 110b includes a sub-array SBi1 (not shown in FIG. 7) configured with respect to the sub-array SB. The sub-array SBi1 is coupled to a bit line BLi1 and a plate line PLi1 The plate line PLi1 is coupled to the power rail R2 that is coupled to the circuit 120. The word line WLi is coupled to both of the sub-arrays SBi and SBi1.

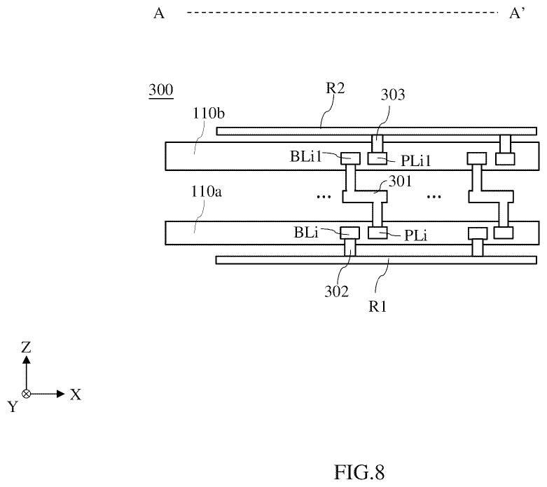

Reference is now made to FIG. 7 and FIG. 8. FIG. 8 is a schematic diagram of a cross-sectional view of the semiconductor device 300 shown in FIG. 7 along a line AA′, in accordance with some embodiments of the present disclosure.

As shown in FIG. 8, the semiconductor device 300 further includes connections 301-303. The bit line BLi1 is coupled to the plate line PLi through the connection 301 (e.g., metal lines and vias). The bit line BLi is coupled to the power rail R1 through the connection 302. The plate line PLi1 is coupled to the power rail R2 through the connection 303.

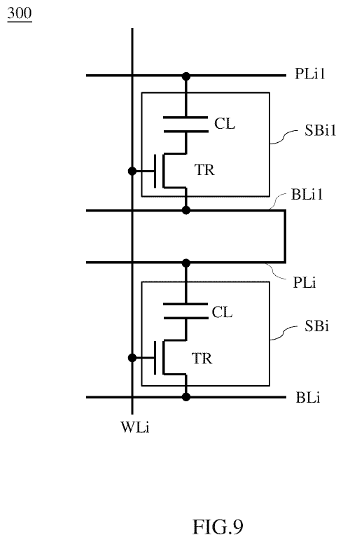

Reference is now made to FIG. 9. FIG. 9 is a schematic diagram of a portion of the semiconductor device 300 shown in FIGS. 7-8, in accordance with some embodiments of the present disclosure.

As shown in FIG. 9, in some embodiments, a bit-line (e.g., bit line BLi1) of one sub-array (e.g., sub-array SBi1) of two adjacent sub-arrays SB is coupled to a plate line (e.g., plate line PLi) of another one sub-array (e.g., sub-array SBi).

For illustration, the lump capacitor CL in the sub-array SBi is coupled to the plate line PLi and further coupled to the transistor TR of the sub-array SBi1 through the bit line BLi1. The transistor TR in the sub-array SBi is coupled between the lump capacitor CL and the bit line BLi.

Similarly, the lump capacitor CL in the sub-array SBi1 is coupled to the plate line PLi1. The drain/source terminal of the transistor TR of the sub-array SBi1 is coupled to the bit line BLi1. Control terminals of the transistors TR in the sub-arrays SBi1 and SBi are coupled to the word line WLi.

The configurations of FIGS. 7-9 are given for illustrative purposes. Various implements are within the contemplated scope of the present disclosure. For example, in some embodiments, the bit-cell array 110a is above the bit-cell array 110b.

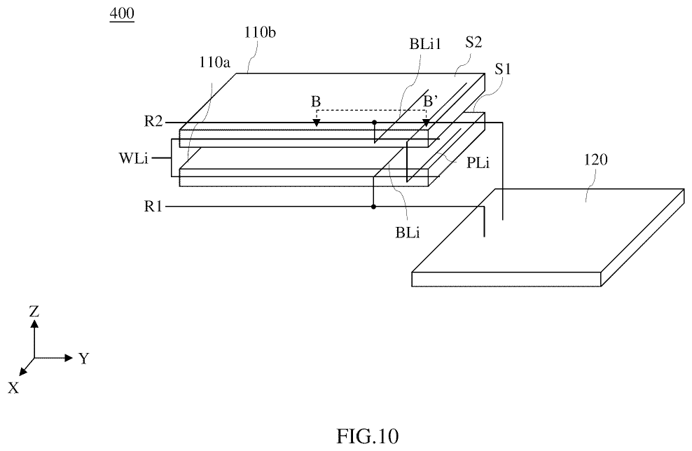

Reference is now made to FIG. 10. FIG. 10 is a schematic diagram of a semiconductor device 400 corresponding to the semiconductor device 300 shown in FIG. 7, in accordance with some embodiments of the present disclosure. With respect to the embodiments of FIGS. 1-9, like elements in FIG. 10 are designated with the same reference numbers for ease of understanding. In some embodiments, the semiconductor device 400 is configured with respect to, for example, the semiconductor device 300 of FIG. 7.

The difference between the semiconductor device 300 and the semiconductor device 400 is that one of the two stacked bit-cell arrays 110 is flipped. For example, the bit-cell array 110b is flipped, and the top side S1 of the bit-cell array 110a and the bottom side of the bit-cell array 110b are arranged toward a same direction (e.g., upward along the z direction). Alternatively stated, the top sides S1 of the bit-cell arrays 110a-110b are arranged face-to-face. As shown in FIG. 10, the bit-cell arrays 110a and 110b share a common plate line (e.g., plate line PLi that is coupled to the bit-cell arrays 110a and 110b).

In addition, the sub-array SBi in the bit-cell array 110a is coupled to a bit line BLi, a plate line PLi and a word line WLi. The bit line BLi is coupled to the power rail R1 that is coupled to the circuit 120. Similarly, the sub-array SBi1 is coupled to a bit line BLi1, the plate line PLi and the word line WLi. The bit line BLi1 is coupled to the power rail R2 that is coupled to the circuit 120.

Reference is now made to FIG. 10 and FIG. 11. FIG. 11 is a schematic diagram of a cross-sectional view of the semiconductor device 400 shown in FIG. 10 along a line BB′, in accordance with some embodiments of the present disclosure.

As shown in FIG. 11, the semiconductor device 400 further includes connections 401-403 (e.g., metal lines and/or vias). The bit line BLi is coupled to the power rail R1 through the connection 402. The bit line BLi1 is coupled to the power rail R2 through the connection 403. The bit line BLi1 is coupled to the plate line PLi through the connection 301. In some embodiments, the plate lines PLi1 and PLi is coupled to each other through the connection 401. In some embodiments, the local plate lines PLP of the sub-arrays SBi and SBi1 are coupled to the common plate line PLi directly.

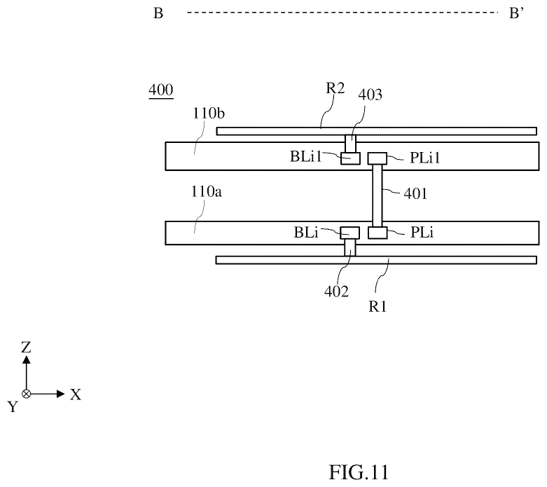

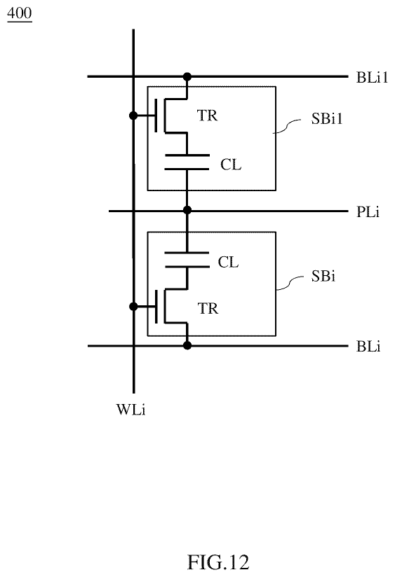

Reference is now made to FIG. 12. FIG. 12 is a schematic diagram of a portion of the semiconductor device 400 shown in FIG. 10, in accordance with some embodiments of the present disclosure.

For illustration, the lump capacitor CL in the sub-array SBi is coupled to the plate line PLi. The drain/source terminal of the transistor TR in the sub-array SBi is coupled to the bit line BLi. Control terminals of the transistors TR in the sub-arrays SBi and SB are coupled to the word line WLi.

Similarly, the lump capacitor CL in the sub-array SBi1 is coupled to the plate line PLi. Drain/source terminals of the transistors TR in the sub-array SBi1 is coupled to the bit line BLi1. Control terminals of the transistors TR in the sub-array SBi1 and SB are coupled to the word line WLi.

The configurations of FIGS. 10-12 are given for illustrative purposes. Various implements are within the contemplated scope of the present disclosure. For example, in some embodiments, the bit-cell array 110a is above the bit-cell array 110b.

According to some embodiments of the present disclosure, the stacked bit-cell arrays provide greater tolerance of voltage between the power rails R1 and R2. For explanation, in some embodiments, tolerance of voltage between the power rails R1 and R2 provided by stacked two bit-cell arrays as shown in FIGS. 7-12 are twice of the tolerance of voltage between the power rails R1 and R2 provided by a single bit-cell array.

Reference is now made to FIG. 13. FIG. 13 is a schematic diagram of a semiconductor device 500 corresponding to the semiconductor device 300 shown in FIG. 7, in accordance with some embodiments of the present disclosure. With respect to the embodiments of FIGS. 1-9, like elements in FIG. 13 are designated with the same reference numbers for ease of understanding. In some embodiments, the semiconductor device 500 is configured with respect to, for example, the semiconductor device 300 of FIG. 7. It should be noted that some portions of the semiconductor device 500 are not shown in FIG. 13 for simplicity.

The difference between the semiconductor device 300 and the semiconductor device 500 is that the semiconductor device 500 includes more than two stacked bit-cell arrays 110. The bit-cell arrays 110 are stacked and connected to each other in the same manner described above with reference to FIGS. 7-9. As shown in FIG. 13, the sub-arrays SB of the stacked bit-cell arrays 110 are connected to each other through adjacent bit lines BL and plate lines PL. For example, a bit line BLi3 of a sub-array SBi3 which is a sub-array SB of one of the stacked bit-cell arrays 110 is coupled to a plate line PLi2 of a sub-array SB2 which is a sub-array SB of an adjacent bit-cell arrays 110 stacked below/above the bit-cell array 110 of the sub-array SBi3.

In some embodiments, a bit line BL (e.g., bit line BLi) of the first bit-cell array 110 in the stacked bit-cell arrays 110 of the he semiconductor device 500 is coupled to the power rail R1. A plate line PL (e.g., bit line PLi3) of the last bit-cell array 110 in the stacked bit-cell arrays 110 of the semiconductor device 500 is coupled to the power rail R2.

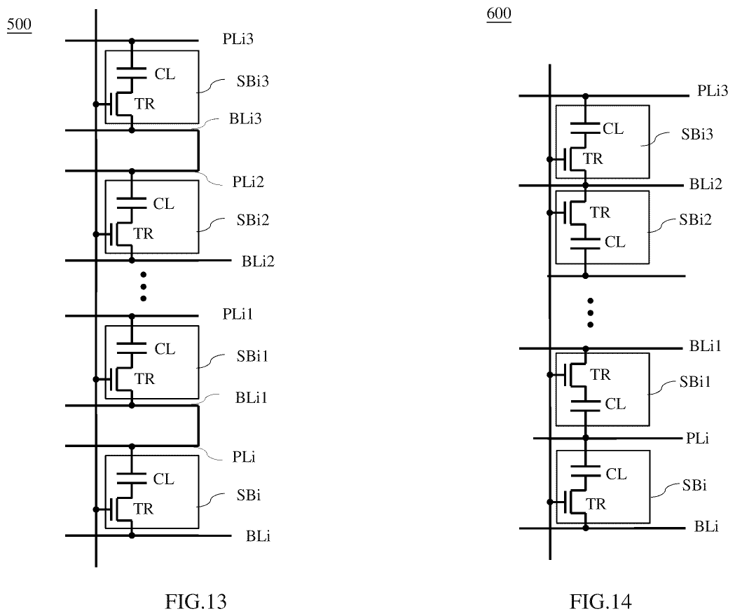

Reference is now made to FIG. 14. FIG. 14 is a schematic diagram of a semiconductor device 600 corresponding to the semiconductor device 400 shown in FIG. 10, in accordance with some embodiments of the present disclosure. With respect to the embodiments of FIGS. 1-12, like elements in FIG. 14 are designated with the same reference numbers for ease of understanding. In some embodiments, the semiconductor device 600 is configured with respect to, for example, the semiconductor device 400 of FIG. 10. It should be noted that some portions of the semiconductor device 600 are not shown in FIG. 14 for simplicity.

The difference between the semiconductor device 400 and the semiconductor device 600 is that the semiconductor device 600 includes more than two stacked bit-cell arrays 110. The bit-cell arrays 110 are stacked and connected to each other in the same manner described above with reference to FIGS. 10-12. As shown in FIG. 14, the even bit-cell arrays 110 of the stacked bit-cell arrays 110 of the semiconductor device 600 are flipped. In various embodiments, the even numbers of bit-cell arrays 110 of the stacked bit-cell arrays 110 of the semiconductor device 600 are flipped. The adjacent sub-arrays SB of the stacked bit-cell arrays 110 have a common plate line PL or a common bit line BL. For example, a sub-array SBi2 is a sub-array SB of one of the stacked bit-cell arrays 110; a sub-array SB3 is a sub-array SB of an adjacent bit-cell arrays 110 stacked below/above the bit-cell array 110 of the sub-array SBi2; and the sub-array SBi2 and the sub-array SB3 are coupled to a common bit line BLi2 as shown in FIG. 14.

In some embodiments, a bit line BL (e.g., bit line BLi) or plate line PL (not a common bit line BL or a common plate line PL) of the first bit-cell array 110 in the stacked bit-cell arrays 110 of the he semiconductor device 600 is coupled to the power rail R1. A plate line PL (e.g., bit line PLi3) or a bit line BL (not a common bit line BL or a common plate line PL) of the last bit-cell array 110 in the stacked bit-cell arrays 110 of the he semiconductor device 600 is coupled to the power rail R2.

Reference is now made to FIG. 15. FIG. 15 is a schematic diagram of a semiconductor device 700 corresponding to the semiconductor devices 300-600 shown in FIGS. 7-14, in accordance with some embodiments of the present disclosure. With respect to the embodiments of FIGS. 1-14, like elements in FIG. 15 are designated with the same reference numbers for ease of understanding. In some embodiments, the semiconductor device 700 is configured with respect to, for example, the semiconductor devices 500-600 of FIGS. 13-14. It should be noted that some portions of the semiconductor device 700 are not shown in FIG. 15 for simplicity.

The difference between the semiconductor device 700 and the semiconductor devices 500-600 is that bit-cell arrays 110 of the semiconductor device 700 are stacked in a manner that is a combination approach of the semiconductor devices 500 and 600. For example, as shown in FIG. 15, sub-arrays SBi, SBi1, SBi2 and SBi3 are sub-arrays SB of stacked bit-cell arrays 110 of the semiconductor device 700; the sub-arrays SBi and SBi1 are stacked in the stacking manner of the semiconductor device 500 as described above; and the sub-arrays SBi2 and SBi3 are stacked in the stacking manner of the semiconductor device 600 as described above.

In some embodiments, a bit line BL (e.g., bit line BLi) or plate line PL (not a common bit line BL or a common plate line PL) of the first bit-cell array 110 in the stacked bit-cell arrays 110 of the he semiconductor device 700 is coupled to the power rail R1. A plate line PL (e.g., bit line PLi3) or a bit line BL (not a common bit line BL or a common plate line PL) of the last bit-cell array 110 in the stacked bit-cell arrays 110 of the he semiconductor device 700 is coupled to the power rail R2.

According to some embodiments, the tolerance of voltage between the power rails R1 and R2 provided by the semiconductor devices 500-700 is proportional to the number of stacked bit-cell arrays 110.

The configurations of FIGS. 13-15 are given for illustrative purposes. Various implements are within the contemplated scope of the present disclosure. For example, in some embodiments, each bit-cell array 110 has multiple sub-arrays SB coupled to the sub-arrays SB of an adjacent bit-cell array 110 stacked above/below.

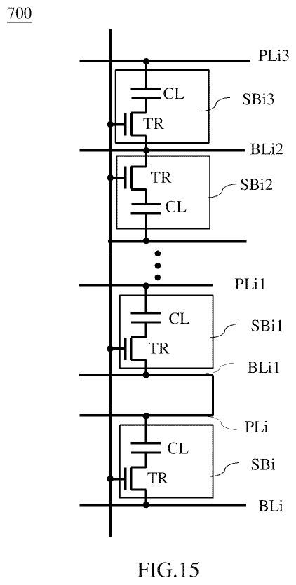

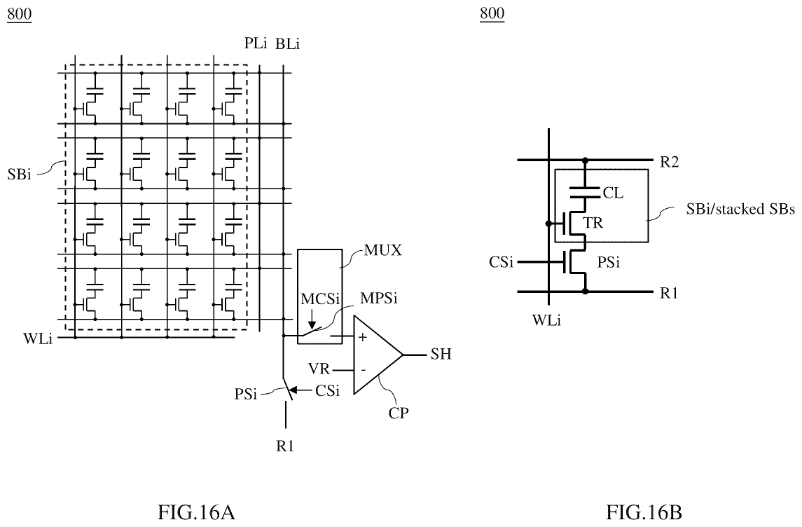

Reference is now made to FIGS. 16A-16B. FIGS. 16A-16B are schematic diagrams of a semiconductor device 800 corresponding to the semiconductor devices 100-700 shown in FIGS. 1-15, in accordance with some embodiments of the present disclosure. With respect to the embodiments of FIGS. 1-15, like elements in FIGS. 16A-16B are designated with the same reference numbers for ease of understanding. In some embodiments, the semiconductor device 800 is configured with respect to, for example, one of the semiconductor devices 100-700 of FIGS. 1-15. It should be noted that some portions of the semiconductor device 800 are not shown in FIGS. 16A-16B for simplicity.

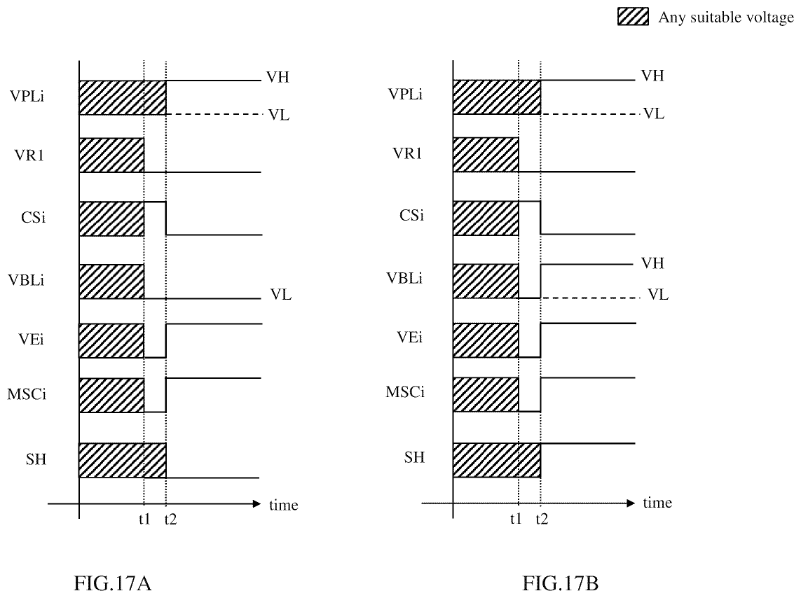

Compared to the semiconductor devices 100-700, the semiconductor device 800 is further configured to perform a test operation and a repair operation. In some embodiments, in the test operation, the control circuit 130 screens a defect sub-array SB (e.g., having short connectivity between the plate line and the bit line BL or having weak bit-cell BC with leakage current). In some embodiments, in the repair operation, the control circuit 130 disables the defect sub-array SB. Detail of the test operation and the repair operation would be described in the paragraphs below with reference to FIGS. 17A-17B.

As shown in FIG. 16A, the difference between the semiconductor device 800 and the semiconductor devices 100-700 is that the semiconductor device 800 further includes a switch PSi coupled between the power rail R1 and the bit line BLi of the sub-array SBi. In addition, the semiconductor device 800 further includes a comparator CP and a multiplexer MUX. The multiplexer MUX includes multiple switches. Each of the switches is coupled between a first input terminal (e.g., a positive input) of the comparator CP and a sub-array SB of the semiconductor device 800. For example, the switch MPSi of the multiplexer MUX is coupled between the first input terminal of the comparator CP and the sub-array SBi.

In addition, the switch MPSi is turned on according to the signal MCSi to couple the bit line BLi to the first input terminal of the comparator CP. A second input terminal (e.g., a negative input) of the comparator CP is coupled to a voltage VR. The comparator CP generates a signal SH at the output terminal of the comparator CP. The switch PSi is turned on according to a signal CSi to couple the bit line BLi to the power rail R1.

As shown in FIG. 16B, the switch PSi may be a transistor. In some embodiment, the switch PSi is an n type transistor. In some embodiment, the switch PSi is an p type transistor.

For illustration, the sub-array SBi or stacked sub-arrays SB (like the sub-array SBi, SBi1, etc. shown in FIGS. 7-15) are coupled between the power rail R2 and a drain/source terminal of the switch PSi. A source/drain terminal of the switch PSi is coupled to the power rail R1. A control terminal (gate terminal) of the switch PSi is coupled to the signal CSi.

For the sake of simplicity, as shown in FIG. 16B, all the capacitors 101 in the sub-array SBi or the stacked sub-arrays SB are represented as a lump capacitor CL and all the transistors 102 in the sub-array SBi or the stacked sub-arrays SB are represented as a transistor TR.

The configurations of FIGS. 16A-16B are given for illustrative purposes. Various implements are within the contemplated scope of the present disclosure. For example, in some embodiments, the semiconductor device 800 includes multiple switches like the switch PSi coupled between the power rail R1 and sub-arrays SB (or stacked sub-arrays). In some embodiments, the switches (e.g., switch PSi) is coupled between the power rail R2 and sub-arrays SB (or stacked sub-arrays) instead of between the power rail R2 and sub-arrays SB (or stacked sub-arrays).

Reference is now made to FIGS. 16A-16B and 17A-17B. FIGS. 17A and 17B are example timing diagrams of voltage signals of the semiconductor device 800 in a test operation, in accordance with some embodiments of the present disclosure.

In some embodiments, the control circuit 130 controls signals on plate lines PL, bit lines BL, word lines WL, switches and the multiplexer MUX to perform a test operation to check connectivity of the plate line PL and bit line BL of each sub-array SB or stacked sub-arrays. For ease of explanation, the following paragraphs only describe examples of the test operation of a single sub-array SB. It should be noted that the test operations to multiple sub-arrays SB and stacked sub-arrays SB can be performed in a similar manner.

For explanation, the voltage signals on the plate line PLi, power rail R1, bit line BLi and word line WLi are annotated as signals VPLi, VR1, VBLi and VEi respectively. In some embodiments, the control circuit 130 (not shown in FIGS. 16A-16B) of the semiconductor device 800 controls the signals VPLi, VR1, CSi, VBLi, VEi and MSCi to perform the test operation to check connectivity of the plate line PLi and bit line BLi. Specifically, the control circuit 130 performs the test operation to determine whether the plate line PLi and the bit line BLi are shorted (or including weak bit-cell BC with current leakage). In some embodiments, the control circuit 130 determines that the sub-array SBi passes the test operation when the plate line PLi and bit line BLi are determined not shorted (or the sub-array SBi not including weak bit-cell BC). In contrast, the control circuit 130 determines that the semiconductors device 800 fails the test operation when the plate line PLi and the bit line BLi are determined shorted (or the sub-array SBi including weak bit-cell BC).

FIG. 17A shows voltage signals of the semiconductor device 800 when the plate line PLi and the bit line BLi are not shorted (or the sub-array SBi not including weak bit-cell BC), and FIG. 17B shows voltage signals of the semiconductor device 800 when the plate line PLi and bit line BLi are shorted (or the sub-array SBi including weak bit-cell BC).

As shown in FIG. 17A-17B, in a test operation, the power rail R1 is applied with a first voltage (e.g, the voltage VL described above). The signal VR1 has the first voltage at a time t1.

In the test operation, at the time t1, the switch PSi is turned on according to the signal CSi. In some embodiments of FIGS. 17A-17B, the switch PSi is an n type transistor, the signal CSi is pulled high to turn on the switch PSi as shown in FIGS. 17A-17B.

In response to the switch PSi turned on, the first voltage from the power rail R1 is applied to the bit line BLi. The signal VBLi has the first voltage at the time t1 in both FIGS. 17A-17B.

In the test operation, the switch MPSi in the multiplexer MUX is turned off initially. In some embodiments, the signal MCSi is inverted from the signal CSi. In some embodiments, the switch MPSi is turned off/on in response to the switch PSi turned on/off. In some embodiments, the switch MPSi is an n type transistor, the signal MCSi is pulled low to turn off the switch MPSi at the time t1 as shown in FIGS. 17A-17B.

In the test operation, the sub-array SBi is not enabled initially. In other word, the transistors 102 coupled to the word line WLi are turned off at the time t1. In some embodiments, the transistors 102 are n type transistors, the signal VEi on the word line WLi is pulled low to turn off the transistors 102 as shown in FIGS. 17A-17B.

At a time t2, the switch PSi is turned off and the switch MPSi is turned on. In some embodiments, the signal CSi is pulled low and the signal MCSi is pulled high at the time t2 as shown in FIGS. 17A and 17B.

At the time t2, the plate line PLi is applied with a second voltage (e.g., voltage VH) from the power rail R2. The signal VPLi has the second voltage at the time t2.

At the time t2, the sub-array SBi is enabled to operate as a decoupling capacitor. In other word, the transistors 102 coupled to the word line WLi are turned on at the time t2. In some embodiments, the transistors 102 are n type transistors, the signal VEi on the word line WLi is pulled high (e.g., to have the voltage VWL) to turn on the transistors 102 as shown in FIGS. 17A-17B.

As shown in FIG. 17A, when the plate line PLi and the bit line BLi is not shorted (or the sub-array SBi not including weak bit-cell BC), at the time t2, the signal VBLi keeps having the first voltage VL. In response to the switch MPSi turned on, the comparator CP compares a voltage of the signal VBLi and the voltage VR at the time t2. In some embodiments, the voltage VR is between the first and second voltages (e.g., VH>VR>VL, when the first and second voltages are the voltages VL and VH respectively). In some embodiments, the voltage VR=VH+VL/2.

The comparator CP generates a signal SH according to the comparison between the voltage of the signal VBLi and the voltage VR at the time t2. In some embodiments, when the voltage of the signal VBLi is lower than the voltage VR, the comparator CP pulled low the signal SH. The control circuit 130 determines that the plate line PLi and the bit line BLi is not shorted (or SBi not including a weak bit-cell BC) according to the signal SH pulled low after the time t2.

As shown in FIG. 17B, when the plate line PLi and the bit line BLi is shorted (or the sub-array SBi including weak bit-cell BC), at the time t2, the voltage from the plate line PLi is transmitted to the bit line BLi. The signal VBLi has the second voltage at the time t2. In response to the switch MPSi turned on, the comparator CP compares a voltage of the signal VBLi and the voltage VR at the time t2. The comparator CP generates the signal SH according to the comparison between the voltage of the signal VBLi and the voltage VR at the time t2. In some embodiments, when the voltage of the signal VBLi is higher than the voltage VR, the comparator CP pulled high the signal SH. The control circuit 130 determines that the plate line PLi and the bit line BLi is shorted (or SBi including a weak bit-cell BC) according to the signal SH pulled high after the time t2.

The following Table 1 shows signals of the semiconductor device 800 in some embodiments. In the Table 1, “1” stands for pulled high, “0” stands for pulled low. “X” stands for unknown. The second row indicates signals in a normal operation (providing decoupling capacitance to the circuit 120). The third row shows signals in a test operation after the time t2 when the plate line PLi and the bit line BLi is not shorted (or the sub-array SBi not including weak bit-cell BC). The fourth row shows signals in a test operation after the time t2 when the plate line PLi and the bit line BLi is shorted (or the sub-array SBi including weak bit-cell BC). The fourth row shows signals in a test operation after the time t2 when the sub-array SBi is not selected (disabled). The fifth row shows signals in a repair operation.

TABLE 1

| | CSi | VEi | VPLi | VR1 | VBLi | SH |
|---|---|---|---|---|---|---|
| Normal operation | 1 | 1 | VH | VL | VL | 0 |
| Testing no short | 0 | 1 | VH | VL | VL | 0 |
| Testing with short | 0 | 1 | VH | VL | VH | 1 |
| Testing un-select | 0 | 0 | VH | VL | X | X |
| block | | | | | | |
| Repair operation | X | 0 | VH | VL | X | X |
| (Short Repaired) | | | | | | |

As shown in Table 1, in a repair operation, the sub-array SBi is disabled. Specifically speaking, when the plate line PLi and the bit line BLi is determined shorted (or the sub-array SBi including weak bit-cell BC), the repair operation is performed to disable the sub-array SBi. In some embodiments, in the repair operation, the control circuit 130 pulls down the signal VEi to disable the sub-array SBi. For example, when the sub-arrays SB are operating to provide decoupling capacitance to the circuit 120, the control circuit 130 performs the repair operation to disable the defect sub-arrays SB among all the sub-arrays SB.

The configurations of FIGS. 16A-16B and 17A-17B are given for illustrative purposes. Various implements are within the contemplated scope of the present disclosure. For example, in some embodiments, the bit line BLi is applied with the voltage VH at the time t1 and the plate line PLi is applied with the voltage VH at the time t2. In some embodiments, the transistor/switch (e.g., transistor 102, switch PSi, etc.) of the semiconductor device 800 is p type, it should be noted that, to perform a similar operation, the control signal for a p type transistor/switch is inverted from the control signal for an n type transistor/switch.

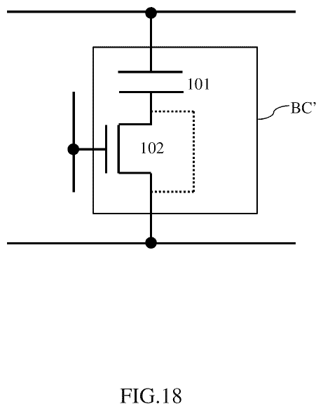

Reference is now made to FIG. 18. FIG. 18 is schematic diagrams of a bit-cell BC′ corresponding to the bit-cell BC in the semiconductor devices 100-800 shown in FIGS. 1-15, in accordance with some embodiments of the present disclosure. With respect to the embodiments of FIGS. 1-15, like elements in FIG. 18 are designated with the same reference numbers for ease of understanding. In some embodiments, the semiconductor device 800 is configured with respect to, for example, the bit-cell BC in the semiconductor device 100-800 shown in FIGS. 1-15.

The difference between the bit-cell BC′ and the bit-cell BC is that the source and drain terminals of the transistor 102 are shorted. In some embodiment, the source and drain terminals of the transistor 102 in the bit-cell BC′ is shorted through a process modification. For example, mask in the manufacture process for the bit cell is modified to extend the source or drain area so that the source and drain terminals touch each other. In some embodiments, the bit-cells BC in the semiconductor device 100-800 shown in FIGS. 1-15 can be replaced by the bit-cells BC′. In some embodiments, the word lines WL coupled to the bit-cells BC′ are floating.

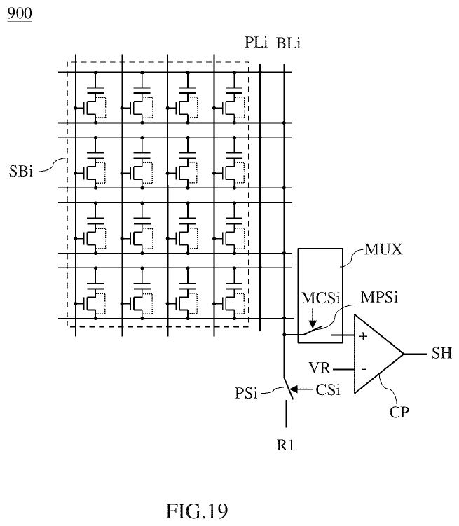

Reference is now made to FIG. 19. FIG. 19 is a schematic diagram of a semiconductor device 900 corresponding to the semiconductor devices 100-800 shown in FIGS. 1-15, 16A-16B and 17A-17B in accordance with some embodiments of the present disclosure. With respect to the embodiments of FIGS. 1-15, 16A-16B and 17A-17B like elements in FIG. 19 are designated with the same reference numbers for ease of understanding. In some embodiments, the semiconductor device 900 is configured with respect to, for example, the semiconductor devices 800 of FIGS. 16A-16B and 17A-17B. It should be noted that some portions of the semiconductor device 900 are not shown in FIG. 19 for simplicity.

As shown in FIG. 19, the difference between the semiconductor device 900 and the semiconductor device 800 is that the semiconductor device 900 has sub-arrays SB with bit-cells BC′ instead of bit-cells BC.

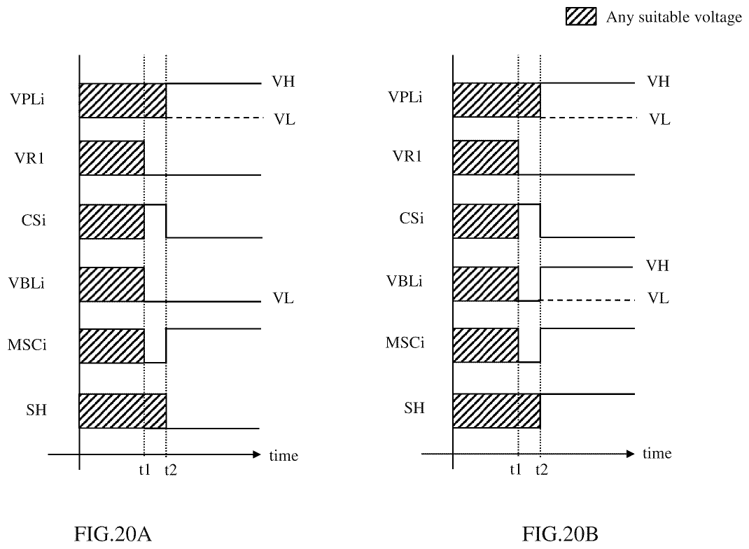

Reference is now made to FIGS. 19 and 20A-20B. FIGS. 20A and 20B are example timing diagrams of voltage signals of the semiconductor device 900 in a test operation, in accordance with some embodiments of the present disclosure. FIG. 20A shows voltage signals of the semiconductor device 900 when the plate line PLi and bit line BLi are not shorted (or the sub-array SBi not including weak bit-cell BC) and FIG. 20B shows voltage signals of the semiconductor device 900 when the plate line PLi and bit line BLi are shorted (or the sub-array SBi including weak bit-cell BC).

The test operation for the semiconductor device 900 is configured with respect to the test operation for the semiconductor device 800 described above. The difference between the test operation for the semiconductor device 800 and the voltage signals for the semiconductor device 900 is that the word line WL is not used to control the semiconductor device 900 for the test operation.

The following Table 2 shows signals of the semiconductor device 900 in some embodiments. In the Table 2, “1” stands for pulled high, “0” stands for pulled low. “X” stands for unknown. The second row indicates signals in a normal operation (providing decoupling capacitance to the circuit 120). The third row shows signals in a test operation after the time t2 when the plate line PLi and the bit line BLi is not shorted (or the sub-array SBi not including weak bit-cell BC). The fourth row shows signals in a test operation after the time t2 when the plate line PLi and the bit line BLi is shorted (or the sub-array SBi including weak bit-cell BC). The fourth row shows signals in a test operation after the time t2 when the sub-array SBi is not selected (disabled). The fifth row shows signals in a repair operation.

TABLE 2

| | CSi | VPLi | VR1 | VBLi | SH |
|---|---|---|---|---|---|
| Normal operation | 1 | VH | VL | VL | 0 |
| Testing no short | 0 | VH | VL | VL | 0 |
| Testing with short | 0 | VH | VL | VH | 1 |
| Testing un-select block | 0 | VH | VL | X | X |
| Repair operation (Short Repaired) | 0 | VH | VL | X | X |

As shown in Table 2, in a repair operation of the semiconductor device 900, the sub-array SBi is disabled. Specifically speaking, when the plate line PLi and the bit line BLi is determined shorted (or the sub-array SBi including weak bit-cell BC), the repair operation is performed to disable the sub-array SBi. In some embodiments, in the repair operation, the control circuit 130 turns off (pull down signal CSi when the switch PSi is an n type transistor) the switch PSi to disable the sub-array SBi. For example, when the sub-arrays SB are operating to provide decoupling capacitance to the circuit 120, the control circuit 130 performs the repair operation to disable the defect sub-arrays SB among all the sub-arrays SB.

In some embodiments, the control circuit 130 controls signals (e.g., voltages on the bit lines BL, plate lines PL and the word lines WL) to the semiconductor devices 100-900 to alter the sub-arrays SB from a decoupling mode (providing decoupling capacitance to the circuit 130) to a memory mode. In the memory mode the sub-arrays SB are used as memory arrays (e.g., DRAM) for storing data.

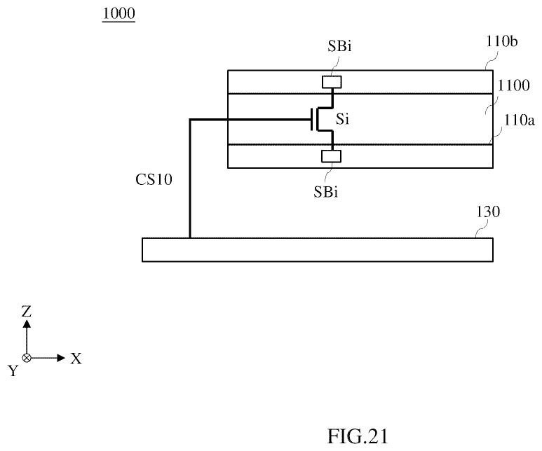

Reference is now made to FIG. 21. FIG. 21 is a schematic diagram of a semiconductor device 1000 corresponding to the semiconductor devices 100-900 shown in FIGS. 1-15, 16A-16B, 17A-17B, 18-19 and 20A-20B in accordance with some embodiments of the present disclosure. With respect to the embodiments of FIGS. 1-15, 16A-16B, 17A-17B, 18-19 and 20A-20B like elements in FIG. 21 are designated with the same reference numbers for ease of understanding. In some embodiments, the semiconductor device 1000 is configured with respect to, for example, the semiconductor devices 100-900. It should be noted that some portions of the semiconductor device 1000 are not shown in FIG. 21 for simplicity.

As shown in FIG. 21, the difference between the semiconductor device 1000 and the semiconductor devices 100-900 is that the bit-cell array 110 of the semiconductor device 1000 further includes a switch (e.g., switch Si) formed in a layer 1001 between each stacked sub-arrays SB (e.g., sub-arrays SBi and SBi1). In some embodiments, the switch between each stacked sub-arrays SB is turned off when one sub-array SB of the stacked sub-arrays SB is altered to memory mode by the control circuit 130. For example, the control circuit 130 turns off the switch Si through a control signal CS10 when the sub-array SBi and/or SBi1 are in a memory mode.

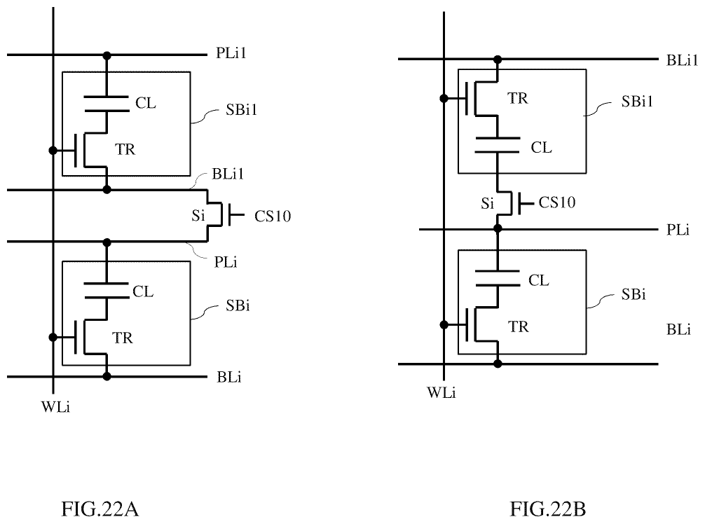

Reference is now made to FIGS. 22A and 22B. FIGS. 22A and 22B are schematic diagrams of a portion of the semiconductor device 1000 shown in FIG. 21 in accordance with some embodiments of the present disclosure. As shown in FIG. 22A, in some embodiments, the switch S1 is coupled between a plate line PL (e.g., PLi) of a sub-array SB (e.g., SBi) and a bit line (e.g., BLi1) of an adjacent stacked sub-array (e.g., SBi1). As shown in FIG. 22B, in some embodiments, the switch S1 is coupled between a plate line PL (e.g., PLi) of a sub-array SB (e.g., SBi) and the lump capacitor CL of an adjacent stacked flipped sub-array (e.g., SBi1).

In some embodiments, the bit-cell arrays 110 include some sub-arrays different from the sub-arrays SB. These sub-arrays different from the sub-arrays SB are used as memory arrays while the sub-arrays SB are used to provide decoupling capacitance.

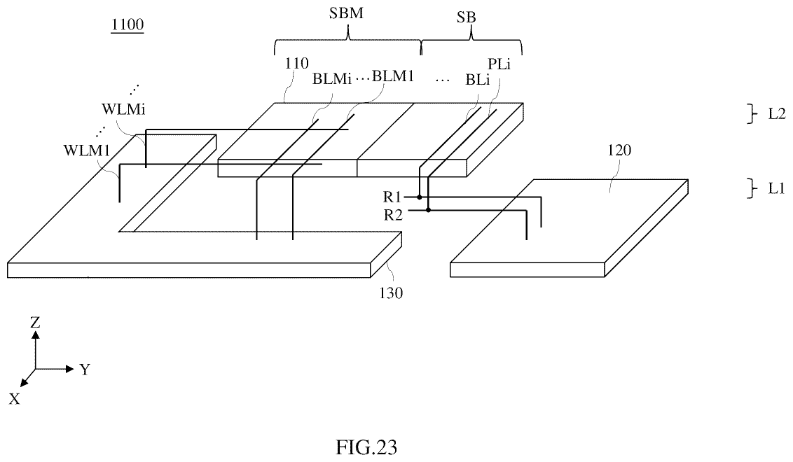

Reference is now made to FIG. 23. FIG. 23 is a schematic diagram of a semiconductor device 1100 corresponding to the semiconductor devices 100-1000 shown in FIGS. 1-15, 16A-16B, 17A-17B, 18-19, 20A-20B, 21 and 22A-22B in accordance with some embodiments of the present disclosure. With respect to the embodiments of FIGS. 1-15, 16A-16B, 17A-17B, 18-19, 20A-20B, 21 and 22A-22B like elements in FIG. 23 are designated with the same reference numbers for ease of understanding. In some embodiments, the semiconductor device 1100 is configured with respect to, for example, the semiconductor devices 100-1000. It should be noted that some portions of the semiconductor device 1100 are not shown in FIG. 22 for simplicity.

As shown in FIG. 23, the difference between the semiconductor device 1100 and the semiconductor devices 100-1000 is that the bit-cell array 110 of the semiconductor device 1100 further includes at least one sub-array SBM that is used as a memory array. For illustration, the sub-array SBM includes multiple bit lines BLM (e.g., bit lines BLM1 to BLMi) and multiple word lines WLM (e.g., word lines WLM1 to WLMi). As shown in FIG. 23, the control circuit 130 is coupled to the sub-array SBM through the bit lines BLM and the word lines WLM. In some embodiments, the control circuit 130 write data to or read data from the sub-array SBM through the bit lines BLM and the word lines WLM.

In some embodiments, the semiconductor devices 100-1100 includes a compute-in-memory (CIM) circuit. In some embodiments, each bit-cell array 110 of the semiconductor devices 100-1100 includes a memory array of the CIM circuit. In some embodiments, each sub-arrays SB of the semiconductor devices 100-1100 is configured as a decoupling capacitor of the CIM circuit. In some embodiments, the sub-array SBM of the semiconductor device 1100 is configured as the memory array of the CIM circuit.

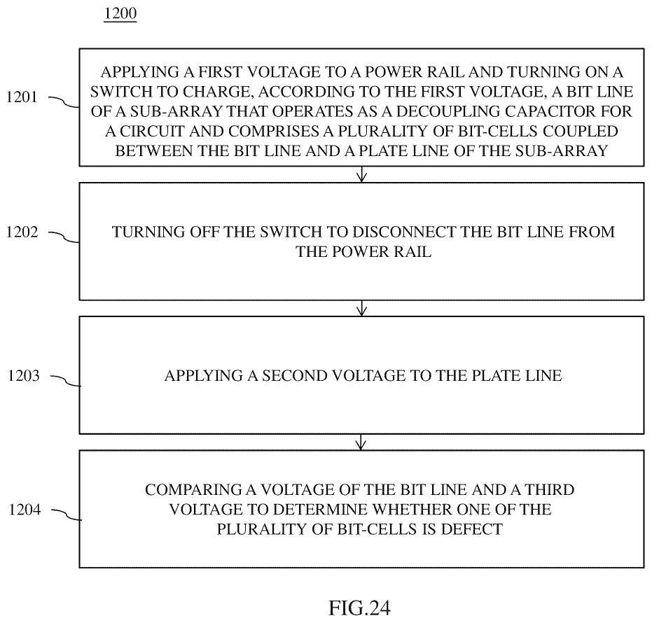

Reference is now made to FIG. 24. FIG. 24 is a flowchart diagram of a method 1200 for operating the semiconductor device 100, 200, . . . 1000 or 1100 shown in FIGS. 1-15, 16A-16B, 17A-17B, 18-19, 20A-20B, 21, 22A-22B and 23, in accordance with some embodiments. It is understood that additional operations can be provided before, during, and after the processes shown by FIG. 24, and some of the operations described below can be replaced or eliminated, for additional embodiments of the method 1200. The order of the operations/processes may be interchangeable. Throughout the various views and illustrative embodiments, like reference numbers are used to designate like elements. The method 1200 includes operations 1201-1204 that are described below with reference to the semiconductor device 100, 200, . . . 1000 or 1100 corresponding to FIGS. 1-15, 16A-16B, 17A-17B, 18-19, 20A-20B, 21, 22A-22B and 23.

In a test operation to the semiconductor device 100, 200, . . . 1000 or 1100, operations 1201-1204 are performed to determine whether a sub-array SB or stacked sub-arrays SB are defect.

In operation 1201, a first voltage (e.g., voltage VL) is applied to the power rail R1 and a switch (e.g., switch PSi) is turned on to charge or discharge, according to the first voltage, a bit line (e.g., bit line BLi) of a sub-array SB. The sub-array SB operates as a decoupling capacitor for the circuit 120 and comprises bit-cells BC coupled between the bit line and a plate line (e.g., plate line PLi) of the sub-array SB.

In operation 1202, the switch is turned off to disconnect the bit line from the power rail.

In operation 1203, a second voltage (e.g., voltage VH) is applied to the plate line through the power rail R2. When the sub-arrays SB includes a defect bit-cell (e.g., a weak bit-cell BC with current leakage or a bit-cell BC that is shorted with capacitor 101 broken), the voltage on the bit line is pulled up or down according to the second voltage on the plate line.

In operation 1204, the comparator CP compares the voltage on the bit line and the reference voltage VR to determine whether one of the bit-cells BC of the sub-array SB is defected. In some embodiments, the reference voltage is between the first voltage and the second voltage.

In one embodiment, the first voltage is smaller than the second voltage, and the sub-array is determined defect according to the voltage of the bit line being greater than the third voltage. In another embodiment, the first voltage is greater than the second voltage, and the sub-array is determined defect according to the voltage of the bit line being smaller than the third voltage.

In some embodiments, in a repair operation, in order to disable the sub-array SB from operating as the decoupling capacitor for the circuit 120, the transistor 102 in each of the bit-cells BC of the sub-array SB is turned off to disconnect the capacitor 101 in each of the bit-cells BC of the sub-array SB from the bit line according to the determination in the operation 1204 indicating that one of the bit-cells BC of the sub-array SB is defected.

In some embodiments, in a normal operation, the transistor 102 in each of the bit-cells BC of the sub-array SB is turned on and the switch coupled between the bit line and the power rail R1 are turned on to couple the capacitor to the power rail R1 to enable the sub-array SB to operate as the decoupling capacitor for the circuit 120.

In some embodiments, in a repair operation, the switch coupled between the bit line and the power rail R1 is turned off to disable the sub-array SB from operating as the decoupling capacitor for the circuit 120 according to determining that one of the plurality of bit-cells is defect.

As described above, the present disclosure provides semiconductor device and method to provide decoupling capacitance. The provided semiconductor device uses same bit-cell arrays (e.g., back-end DRAM bit-cells) of a memory array without additional fabrication cost for decoupling capacitor applications. The provided method includes a test operation to screen defect sub-array and a repair operation to bypass defect bit-cells. In addition, stacking schemes of the provided semiconductor device allow higher voltage usage. The semiconductor device and method of the present disclosure provide larger capacitor per unit area and lower current leakage compared to some approaches.

In some embodiments, a semiconductor device is provided. The semiconductor device includes a circuit and a first bit-cell array. The circuit is coupled to a first power rail and a second power rail. The first bit-cell array comprises a first sub-array having multiple first bit-cells that are coupled between the first power rail and the second power rail. When the circuit operates in response to a first operational voltage on the first power rail and a second operational voltage on the second power rail, the first bit-cells are configured as a decoupling capacitor between the first and second power rails for the circuit.

In some embodiments, the bit-cell array is a back-end dynamic random-access memory array.

In some embodiments, the circuit is arranged in a front-end-of-line layer and the bit-cell array is arranged in a back-end-of-line layer.

In some embodiments, the semiconductor device further includes a second bit-cell array that is stacked on the first bit-cell array and comprises a second sub-array having a plurality of second bit-cells that are coupled between the second power rail and the plurality of first bit-cells. The plurality of first bit-cells and the plurality of second bit-cells are configured as the decoupling capacitor between the first and second power rails for the circuit.

In some embodiments, the semiconductor device further includes a metal connection in a layer between the first and second bit-cell arrays, wherein the metal connection is coupled to a plate line of the first sub-array and one of a plate line and a bit line of the second sub-array.

In some embodiments, the metal connection includes first and second vias that are separated from each other in a horizontal direction.

In some embodiments, the semiconductor device further includes: a bit line coupled between the first power rail and the first sub-array; and a plate line coupled between the second power rail and the first sub-array. Each bit cell of the plurality of first bit cells comprises: a transistor having a first terminal coupled to the bit line; and a capacitor coupled between the plate line and a second terminal of the transistor.

In some embodiments, the semiconductor device further includes: a comparator; and a switch coupled between the bit line and the first power rail. In in a test operation, the switch is turned on to charge the bit line to have the first operational voltage and then turned off to disconnect the bit line and the first power rail. When the switch is turned off, the comparator compares a voltage on the bit line with a reference voltage to determine whether the first sub-array has a weak bit cell or not.

In some embodiments, the semiconductor device further includes: a word line, wherein a control terminal of the transistor of each bit cell of the plurality of first bit cells is coupled to the word line. In a repair operation, the transistor of each bit cell of the plurality of first bit cells is turned off in response to a control signal on the word line according to the determining that the first sub-array has a weak bit cell.

In some embodiments, in a repair operation, according to determining that the first sub-array has a weak bit cell, the switch is turned off to disable the plurality of first bit-cells from operating as the decoupling capacitor.

In some embodiments, the first bit-cell array further includes a second sub-array configured as a memory array to store data.

In some embodiments, a semiconductor device is provided. The semiconductor device comprises a circuit and a first bit-cell array. The circuit operates with first and second supply voltages on first and second power rails respectively. The first bit-cell array comprises multiple first bit-cells arranged in multiple rows and multiple columns. Each row of the rows is coupled to one of local bit lines and one of local plate lines. A first bit line of the first bit-cell array is coupled between the first bit-cells and the first power rail. A first plate line of the first bit-cell array is coupled between the first bit-cells and the second power rail. The local bit lines are coupled to the first bit line and the local plate lines are coupled to the first plate line. Each of the plurality of first bit-cells comprises a capacitor. The first bit-cells are configured as a decoupling capacitor of the circuit between the first and second power rails.

In some embodiments, the semiconductor device further includes: a second bit-cell array that is stacked on the first bit-cell array and comprises a plurality of second bit-cells, in which a second plate line of the second bit-cell array is coupled between the plurality of second bit-cells and the second power rail, and a second bit line of the second bit-cell array is coupled to the first bit line, in which the first and second bit-cell arrays are configured as the decoupling capacitor of the circuit between the first and second power rails.

In some embodiments, the semiconductor device further includes: a second bit-cell array that is stacked on the first bit-cell array and comprises a plurality of second bit-cells, in which the second bit-cell array is flipped in comparison to the first bit-cell array, a second bit line of the second bit-cell array is coupled between the plurality of second bit-cells and the second power rail, and the first plate line is a common plate line of the first and second bit-cell array, in which the first and second bit-cell arrays are configured as the decoupling capacitor of the circuit between the first and second power rails.

In some embodiments, the semiconductor device further includes: a plurality of second bit-cell arrays that stacked on the first bit-cell array, in which the first bit-cell array and the plurality of second bit-cell arrays are coupled between the first and second power rails and configured as the decoupling capacitor of the circuit.

In some embodiments, the first voltage has a negative voltage level and the second voltage has a grounded voltage level.

In some embodiments, a method for operating a semiconductor device is provided. The method comprises: applying a first voltage to a power rail and turning on a switch to charge, according to the first voltage, a bit line of a sub-array that operates as a decoupling capacitor for a circuit and comprises multiple bit-cells coupled between the bit line and a plate line of the sub-array; turning off the switch to disconnect the bit line from the power rail; applying a second voltage to the plate line and comparing a voltage of the bit line and a third voltage to determine whether one of the plurality of bit-cells is defect.

In some embodiments, comparing the voltage of the bit line and the third voltage includes: determining that the sub-array is defect according to the voltage of the bit line being greater than the third voltage.

In some embodiments, the method further includes: in a repair operation, turning off a transistor in each bit-cell of the plurality of bit-cells to disconnect a capacitor in each bit-cell of the plurality of bit-cells from the bit line according to determine that one of the plurality of bit-cells is defect.

In some embodiments, the method further includes: in a normal operation, turning on the transistor in each bit-cell of the plurality of bit-cells and turning on the switch to couple the capacitor to the power rail to enable the sub-array to operate as the decoupling capacitor for the circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a circuit coupled to a first power rail and a second power rail; and
a first bit-cell array comprising a first sub-array having a plurality of first bit-cells that are coupled between the first power rail and the second power rail,
wherein in response to a first operational voltage on the first power rail and a second operational voltage on the second power rail, the plurality of first bit-cells are configured as a decoupling capacitor between the first and second power rails for the circuit.

2. The semiconductor device of claim 1, wherein the first bit-cell array is a back-end dynamic random-access memory array.

3. The semiconductor device of claim 1, wherein the circuit is arranged in a front-end-of-line layer and the first bit-cell array is arranged in a back-end-of-line layer.

4. The semiconductor device of claim 1, further comprising:
a second bit-cell array that is stacked on the first bit-cell array and comprises a second sub-array having a plurality of second bit-cells that are coupled between the second power rail and the plurality of first bit-cells, wherein the plurality of first bit-cells and the plurality of second bit-cells are configured as the decoupling capacitor between the first and second power rails for the circuit.

5. The semiconductor device of claim 4, further comprising a metal connection in a layer between the first and second bit-cell arrays, wherein the metal connection is coupled to a plate line of the first sub-array and one of a plate line and a bit line of the second sub-array.

6. The semiconductor device of claim 5, wherein the metal connection comprising first and second vias that are separated from each other in a horizontal direction.

7. The semiconductor device of claim 1, further comprising:
a bit line coupled between the first power rail and the first sub-array; and
a plate line coupled between the second power rail and the first sub-array,
wherein each bit cell of the plurality of first bit-cells comprises:
a transistor having a first terminal coupled to the bit line; and
a capacitor coupled between the plate line and a second terminal of the transistor.

8. The semiconductor device of claim 7, further comprising:
a comparator; and
a switch coupled between the bit line and the first power rail,
wherein in a test operation, the switch is configured to be turned on to charge the bit line to have the first operational voltage and then turned off to disconnect the bit line and the first power rail,
wherein when the switch is turned off, the comparator is configured to compare a voltage on the bit line with a reference voltage to determine whether the first sub-array has a weak bit cell or not.

9. The semiconductor device of claim 8, further comprising:
a word line, wherein a control terminal of the transistor of each bit cell of the plurality of first bit cells is coupled to the word line,
wherein in a repair operation, the transistor of each bit cell of the plurality of first bit-cells is turned off in response to a control signal on the word line according to the determining that the first sub-array has a weak bit cell.

10. The semiconductor device of claim 8, wherein in a repair operation, according to determining that the first sub-array has a weak bit cell, the switch is turned off to disable the plurality of first bit-cells from operating as the decoupling capacitor.

11. The semiconductor device of claim 1, wherein the first bit-cell array further comprises a second sub-array configured as a memory array to store data.

12. A semiconductor device, comprising:
a circuit configured to operate with a first supply voltage and a second supply voltage on first and second power rails respectively; and
a first bit-cell array comprising a plurality of first bit-cells arranged in a plurality of rows and a plurality of columns, wherein each row of the plurality of rows is coupled to one of a plurality of local bit lines and one of a plurality of local plate lines,
wherein a first bit line of the first bit-cell array is coupled between the plurality of first bit-cells and the first power rail,
a first plate line of the first bit-cell array is coupled between the plurality of first bit-cells and the second power rail,
the plurality of local bit lines are coupled to the first bit line and the plurality of local plate lines are coupled to the first plate line,
each of the plurality of first bit-cells comprises a capacitor, and
wherein the plurality of first bit-cells are configured as a decoupling capacitor of the circuit between the first and second power rails.

13. The semiconductor device of claim 12, further comprising:
a second bit-cell array that is stacked on the first bit-cell array and comprises a plurality of second bit-cells,
wherein a second plate line of the second bit-cell array is coupled between the plurality of second bit-cells and the second power rail, and
a second bit line of the second bit-cell array is coupled to the first bit line,
wherein the first and second bit-cell arrays are configured as the decoupling capacitor of the circuit between the first and second power rails.

14. The semiconductor device of claim 12, further comprising:
a second bit-cell array that is stacked on the first bit-cell array and comprises a plurality of second bit-cells,
wherein the second bit-cell array is flipped in comparison to the first bit-cell array,
a second bit line of the second bit-cell array is coupled between the plurality of second bit-cells and the second power rail, and
the first plate line is a common plate line of the first and second bit-cell array,
wherein the first and second bit-cell arrays are configured as the decoupling capacitor of the circuit between the first and second power rails.

15. The semiconductor device of claim 12, further comprising:
a plurality of second bit-cell arrays that stacked on the first bit-cell array,
wherein the first bit-cell array and the plurality of second bit-cell arrays are coupled between the first and second power rails and configured as the decoupling capacitor of the circuit.

16. The semiconductor device of claim 12, wherein the first supply voltage has a negative voltage level and the second supply voltage has a grounded voltage level.

17. A method for operating a semiconductor device, comprising:
applying a first voltage to a power rail;
turning on a switch to charge, according to the first voltage, a bit line of a sub-array, wherein the sub-array operates as a decoupling capacitor for a circuit and the sub-array comprises a plurality of bit-cells coupled between the bit line and a plate line of the sub-array;
turning off the switch to disconnect the bit line from the power rail;
applying a second voltage to the plate line; and
comparing a voltage of the bit line and a third voltage to determine whether one of the plurality of bit-cells is defect.

18. The method of claim 17, wherein comparing the voltage of the bit line and the third voltage comprises:
determining that the sub-array is defect according to the voltage of the bit line being greater than the third voltage.

19. The method of claim 17, further comprising:
in a repair operation, turning off a transistor in each bit-cell of the plurality of bit-cells to disconnect a capacitor in each bit-cell of the plurality of bit-cells from the bit line according to determine that one of the plurality of bit-cells is defect.

20. The method of claim 19, further comprising:
in a normal operation, turning on the transistor in each bit-cell of the plurality of bit-cells and turning on the switch to couple the capacitor to the power rail to enable the sub-array to operate as the decoupling capacitor for the circuit.
